(19) United States
(12) Patent Application Publication
(10) Pub. No.: US 2023/0290873 A1
(43) Pub. Date: Sep. 14, 2023

(54) HIGH ELECTRON MOBILITY TRANSISTOR STRUCTURE AND METHOD OF MANUFACTURING THE SAME

(71) Applicant: GLOBALWAFERS CO., LTD., Hsinchu City (TW)

(72) Inventors: PO-JUNG LIN, Hsinchu City (TW); JIA-ZHE LIU, Hsinchu City (TW)

(73) Assignee: GLOBALWAFERS CO., LTD., Hsinchu City (TW)

(21) Appl. No.: 17/989,515

(22) Filed: Nov. 17, 2022

(30) Foreign Application Priority Data
Mar. 14, 2022 (TW) 111109214

(51) Int. Cl. H01L 29/778; H01L 29/66; H01L 29/20; H01L 29/10

(52) U.S. Cl. CPC H01L 29/7787; H01L 29/66462; H01L 29/2003; H01L 29/1029

(57) ABSTRACT

An improved high electron mobility transistor (HEMT) structure includes in order a substrate, a nucleation layer, a buffer layer, a channel layer, and a barrier layer, wherein the buffer layer includes a dopant. The channel layer having a dopant doping concentration less than that of the buffer layer. A two-dimension electron gas is formed in the channel layer along an interface between the channel layer and the barrier layer. A dopant doping concentration of the channel layer at an interface between the channel layer and the barrier layer is equal to or greater than 1×10¹⁵ cm⁻³.

### BACKGROUND OF THE INVENTION

### Technical Field

The present invention relates generally to a semiconductor technology, and more particularly to a high electron mobility transistor.

### Description of Related Art

A high electron mobility transistor (HEMT) is typically a transistor having a two-dimensional electron gas (2-DEG) that is located close to a heterojunction of two materials with different energy gaps. As the HEMT makes use of the 2-DEG having a high electron mobility as a carrier channel of the transistor instead of a doped region, the HEMT has features of a high breakdown voltage, the high electron mobility, a low on-resistance, and a low input capacitance, thereby could be widely applied to high power semiconductor devices.

In order to improve the performance of the HEMT, doping is generally performed on a buffer layer of HEMT. However, a dopant in the buffer layer would diffuse to a channel layer and cause a problem of increasing a sheet resistance value of the channel layer for example. Therefore, how to reduce the influence of the dopant to the sheet resistance value of the channel layer and provide a HEMT having a better performance is a problem needed to be solved in the industry.

### BRIEF SUMMARY OF THE INVENTION

In view of the above, the primary objective of the present invention is to provide a high electron mobility transistor structure and a method of manufacturing the same, which could reduce an influence of a dopant to a sheet resistance value of a channel layer and provide a high electron mobility transistor having a better performance.

The present invention provides an improved high electron mobility transistor (HEMT) structure including in order a substrate, a nucleation layer, a buffer layer, a channel layer, and a barrier layer, wherein the buffer layer includes a dopant. The channel layer having a dopant doping concentration less than a dopant doping concentration of the buffer layer. A two-dimension electron gas is formed in the channel layer along an interface between the channel layer and the barrier layer. A dopant doping concentration of the channel layer at an interface between the channel layer and the barrier layer is equal to or greater than 1×10¹⁵ cm⁻³.

The present invention further provides a method of manufacturing an improved high electron mobility transistor (HEMT) structure, comprising steps of provide a substrate; form a nucleation layer on a top of the substrate; form a buffer layer on a top of the nucleation layer and simultaneously perform a doping process; form a channel layer on a top of the buffer layer; and form a barrier layer on a top of the channel layer, wherein a two-dimension electron gas is formed in the channel layer along an interface between the channel layer and the barrier layer; wherein a dopant doping concentration of the channel layer at an interface between the channel layer and the barrier layer is equal to or greater than 1×10¹⁵ cm⁻³.

With the aforementioned design, as the dopant doping concentration of the channel layer at the interface between the channel layer and the barrier layer is equal to or greater than 1×10¹⁵ cm⁻³, the influence of the metal dopant to the sheet resistance value of the nitride channel layer could be reduced and the improved HEMT structure having a better performance could be provided.

### BRIEF DESCRIPTION OF THE SEVERAL VIEWS OF THE DRAWINGS

The present invention will be best understood by referring to the following detailed description of some illustrative embodiments in conjunction with the accompanying drawings, in which

FIG. 1 is a schematic view showing the improved HEMT structure according to an embodiment of the present invention;

FIG. 2 is a flowchart of the method of manufacturing the HEMT structure according to an embodiment of the present invention;

FIG. 3 is a flowchart of the method of manufacturing the HEMT structure with the nitride channel layer having the optimum thickness and the optimum metal doping concentration according to an embodiment of the present invention;

FIG. 4 is a schematic view showing a relationship between the iron atom doping concentration and the thickness according to the embodiment of the present invention; and

FIG. 5 is a schematic view showing a relationship between the sheet resistance value and the iron atom doping concentration according to the embodiment of the present invention.

### DETAILED DESCRIPTION OF THE INVENTION

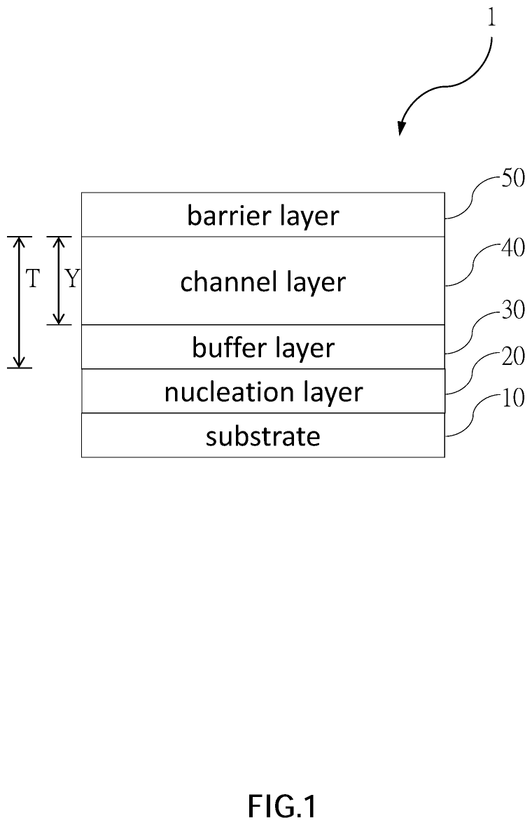

An improved high electron mobility transistor (HEMT) structure according to an embodiment of the present invention is illustrated in FIG. 1 and includes a substrate 10, a nucleation layer 20, a buffer layer 30, a channel layer 40, and a barrier layer 50 in order, and could be formed on the substrate 10 through metal organic chemical vapor deposition (MOCVD).

The substrate 10 is a substrate with a resistivity greater than or equal to 1000 Ω/cm, and could be a silicon carbide (SiC) substrate, a sapphire substrate, or a silicon (Si) substrate for example.

The nucleation layer 20 is a nitride nucleation layer made of aluminum nitride (AlN) or aluminum-gallium nitride (AlGaN), and is located between the substrate 10 and the buffer layer 30.

The buffer layer 30 includes a dopant. In the current embodiment, the buffer layer 30 is a nitride buffer layer made of gallium nitride as an example, and the dopant is a metal dopant, and more specifically iron as an example, wherein a dopant doping concentration of the buffer layer 30 is greater than or equal to 2×10¹⁷ cm⁻³, and a metal doping concentration of an interface between the buffer layer 30 and the channel layer 40 is greater than or equal to 2×10¹⁷ cm⁻³.

The channel layer 40 is a nitride channel layer made of aluminum-gallium nitride or gallium nitride as an example. A two-dimensional electron gas is formed in the channel layer 40 along an interface between the channel layer 40 and the barrier layer 50. In an embodiment, the buffer layer 30 and the channel layer 40 are respectively constituted by an identical and evenly distributed nitride, wherein a thickness Y of the channel layer 40 ranges between 0.6 μm and 1.2 μm, and a total thickness T of the buffer layer 30 and the channel layer 40 is less than or equal to 2 μm; a metal doping concentration, which is a concentration of iron atoms, of the channel layer 40 is less than that of the buffer layer 30 and gradually decreases in a direction from the interface between the buffer layer 30 and the channel layer 40 to the interface between the channel layer 40 and the barrier layer 50. In other embodiments, the concentration of iron atoms could be distributed in the buffer layer 30 and the channel layer 40 in a different way.

In an embodiment, the dopant doping concentration of the buffer layer 30 is evenly distributed on an identical thickness of the buffer layer 30, and a dopant doping concentration of the channel layer 40 is evenly distributed on an identical thickness of the channel layer 40, wherein the thickness of the buffer layer 30 is a distance from an interface between the buffer layer 30 and the nucleation layer 20 to a top surface of the buffer layer 30 or a distance of the buffer layer 30 extending from the interface between the buffer layer 30 and the nucleation layer 20 toward the channel layer 40, and the thickness Y of the channel layer 40 is a distance from the interface of the channel layer 40 and the buffer layer 30 to a top surface of the channel layer 40 or a distance of the channel layer 40 extending from the interface of the channel layer 40 and the buffer layer 30 toward the barrier layer 50. Preferably, a metal doping concentration of the buffer layer 30 on the identical thickness of the buffer layer 30 satisfies (a maximum value of the metal doping concentration of the buffer layer 30−a minimum value of the metal doping concentration of the buffer layer 30)/the maximum value of the metal doping concentration of the buffer layer 30≤0.2, and a metal doping concentration of the channel layer 40 on the identical thickness of the channel layer 40 satisfies (a maximum value of the metal doping concentration of the channel layer 40−a minimum value of the metal doping concentration of the channel layer 40)/the maximum value of the metal doping concentration of the channel layer 40≤0.2.

In the current embodiment, a dopant doping concentration of the channel layer 40 at the interface between the channel layer 40 and the barrier layer 50 is equal to or greater than 1×10¹⁵ cm⁻³. In another embodiment, the dopant doping concentration of the interface between the channel layer 40 and the barrier layer 50 could be equal to or greater than 1×10¹⁶ cm⁻³ and is less than or equal to 2×10¹⁷ cm⁻³.

A metal doping concentration X of the interface between the nitride buffer layer 30 and the nitride channel layer 40 is defined as the number of metal atoms per cubic centimeter. The thickness Y of the nitride channel layer 40 is in microns (μm) and satisfies Y≤(0.2171)ln(X)−8.34. Preferably, the thickness Y of the nitride channel layer 40 satisfies (0.2171)ln(X)−8.54≤Y. In this way, an influence of the metal dopant to a sheet resistance value of the nitride channel layer 40 could be reduced and the improved HEMT structure having a better performance could be provided. When the metal doping concentration X is a constant, a maximum value of the thickness Y of the nitride channel layer 40 could be calculated, thereby obtaining an optimum range of the thickness Y of the nitride channel layer 40 corresponding to the metal doping concentration X. When the thickness Y of the nitride channel layer 40 is a constant, a minimum value of the metal doping concentration X could be calculated, thereby obtaining an optimum range of the metal doping concentration corresponding to the thickness Y of the nitride channel layer 40.

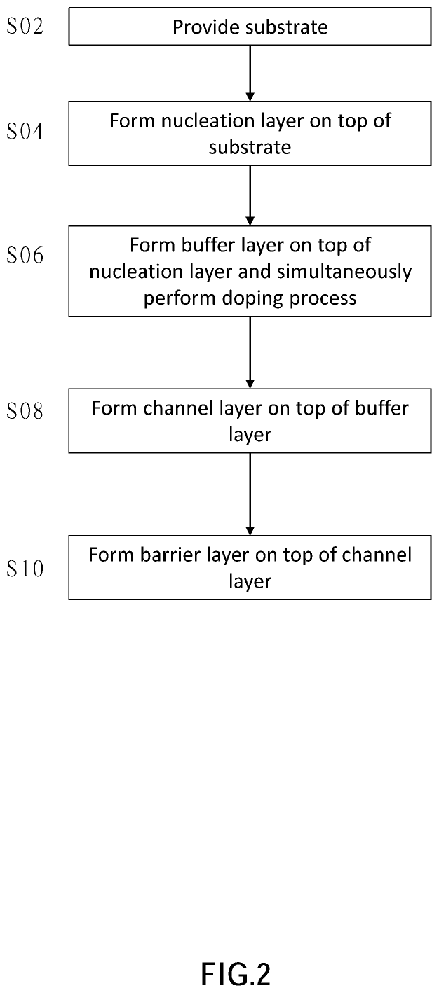

A method of manufacturing a high electron mobility transistor (HEMT) structure according to an embodiment of the present invention is illustrated in a flowchart as shown in FIG. 2, and the HEMT structure of the present invention could be formed on a substrate through metal organic chemical vapor deposition (MOCVD). The method of manufacturing the HEMT structure includes following steps:
step S02: providing a substrate 10, wherein the substrate 10 is a substrate with a resistivity equal to or greater than 1000 Ω/cm; for example, the substrate 10 could be a SiC substrate, a sapphire substrate, or a Si substrate;
step S04: forming a nucleation layer 20 on a top of the substrate 10, wherein the nucleation layer 20 is aluminum nitride (AlN) or aluminum-gallium nitride (AlGaN);
step S06: forming a buffer layer 30 on a top of the nucleation layer 20 and simultaneously performing a doping process; the buffer layer 30 is a nitride buffer layer, wherein epitaxial growth conditions of the nitride buffer layer satisfy a temperature between 1030 degrees Celsius and 1070 degrees Celsius, a pressure between 150 torr and 250 torr, and a V/III ratio between 200 and 1500; a dopant doping concentration in the doping process is equal to or greater than 2×10¹⁷ cm⁻³, and a metal doped in the doping process is iron; the metal doping process includes controlling a flow rate of ferrocene (Cp₂Fe) at a constant, thereby obtaining the buffer layer 30 having a dopant doping concentration that is evenly distributed on an identical thickness of the buffer layer 30; preferably, a metal doping concentration of the buffer layer 30 on the identical thickness of the buffer layer 30 satisfies (a maximum value of the metal doping concentration of the buffer layer 30−a minimum value of the metal doping concentration of the buffer layer 30)/the maximum value of the metal doping concentration of the buffer layer 30≤0.2;
step S08: forming a channel layer 40 on a top of the buffer layer 30; the channel layer 40 is a nitride channel layer, wherein epitaxial growth conditions of the nitride channel layer satisfy a temperature between 1030 degrees Celsius and 1070 degrees Celsius, a pressure between 150 torr and 250 torr, and a V/III ratio between 200 and 1500; a metal doping concentration of an interface between the nitride buffer layer and the nitride channel layer is equal to or greater than 2×10¹⁷ cm⁻³; in the current embodiment, the step S08 includes stopping the metal doping process and forming the channel layer 40 having a thickness Y (in μm), wherein the thickness Y is a distance from the interface between the buffer layer 30 and the channel layer 40 to a top surface of the channel layer 40; a total thickness of the buffer layer 30 and the channel layer 40 is less than or equal to 2 μm and is a distance from an interface between the buffer layer 30 and the nucleation layer 20 to the top surface of the channel layer 40; iron atoms in the buffer layer 30 diffuse from the interface between the buffer layer 30 and the channel layer 40 to the channel layer 40, making an iron atom concentration in the channel layer 40 decrease gradually in a direction from the interface between the buffer layer 30 and the channel layer 40 to the top surface of the channel layer 40;
wherein a metal doping concentration X of the interface between the nitride buffer layer 30 and the nitride channel layer 40 is defined as X number of metal atoms per cubic centimeter, and the thickness Y of the nitride channel layer 40 satisfies Y≤(0.2171)ln(X)−8.34; preferably, the thickness Y of the nitride channel layer 40 satisfies (0.2171)ln(X)−8.54≤Y;
step S10: forming a barrier layer 50 on a top of the channel layer 40; a two-dimensional electron gas is formed in the channel layer 40 along an interface between the channel layer 40 and the barrier layer 50, wherein a dopant doping concentration of the channel layer 40 at the interface between the channel layer 40 and the barrier layer 50 is equal to or greater than 1×10¹⁵ cm⁻³; preferably, the dopant doping concentration of the channel layer 40 at the interface between the channel layer 40 and the barrier layer 50 is equal to or greater than 1×10¹⁶ cm⁻³ and is less than or equal to 2×10¹⁷ cm⁻³.

In the current embodiment, each of the buffer layer 30 and the channel layer 40 is constituted by evenly distributed gallium nitride, and a dopant doping concentration of the buffer layer 30 is evenly distributed on an identical thickness of the buffer layer 30, and a dopant doping concentration of the channel layer 40 is evenly distributed on an identical thickness of the channel layer 40. A thickness of the buffer layer 30 is a distance from an interface between the buffer layer 30 and the nucleation layer 20 to a top surface of the buffer layer 30 or a distance of the buffer layer 30 extending from an interface between the buffer layer 30 and the nucleation layer 20 toward the channel layer 40, the thickness Y of the channel layer 40 is a distance from the interface of the channel layer 40 and the buffer layer 30 to a top surface of the channel layer 40 or a distance of the channel layer 40 extending from the interface of the channel layer 40 and the buffer layer 30 toward the barrier layer 50. Preferably, a metal doping concentration of the buffer layer 30 on the identical thickness of the buffer layer 30 satisfies (a maximum value of the metal doping concentration of the buffer layer 30−a minimum value of the metal doping concentration of the buffer layer 30)/the maximum value of the metal doping concentration of the buffer layer 30≤0.2, and a metal doping concentration of the channel layer 40 on the identical thickness of the channel layer 40 satisfies (a maximum value of the metal doping concentration of the channel layer 40−a minimum value of the metal doping concentration of the channel layer 40)/the maximum value of the metal doping concentration of the channel layer 40≤0.2.

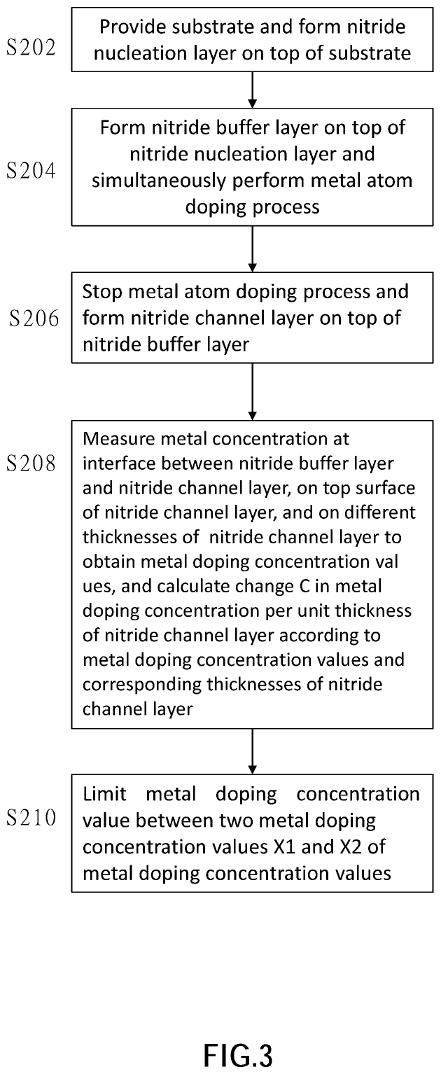

A method of manufacturing a high electron mobility transistor (HEMT) with a nitride channel layer having an optimum thickness and an optimum metal doping concentration is illustrated in FIG. 3 and includes following steps:
step S202: providing a substrate 10 and forming a nitride nucleation layer 20 on a top of the substrate 10;
step S204: forming a nitride buffer layer 30 on a top of the nitride nucleation layer 20 and simultaneously performing a metal atom doping process;
step S206: stopping the metal atom doping process and forming a nitride channel layer 40 on a top of the nitride buffer layer 30;
step S208: measuring a metal concentration at an interface between the nitride buffer layer 30 and the nitride channel layer 40, on a top surface of the nitride channel layer 40, and at different thicknesses of the nitride channel layer 40 to obtain a plurality of metal doping concentration values and calculating a change C in a metal doping concentration per unit thickness of the nitride channel layer 40 based on the metal doping concentration values and the corresponding thicknesses of the nitride channel layer 40;
step S210: limiting a metal doping concentration value between two metal doping concentration values X1 and X2 of the metal doping concentration values, thereby when a metal doping concentration of the nitride buffer layer 30 at the interface between the nitride buffer layer 30 and the nitride channel layer 40 is X, and a thickness of the nitride channel layer 40 is Y, and X1≤X−C*Y≤X2 is satisfied, the optimum metal doping concentration value and the corresponding thickness of the nitride channel layer could be obtained; the step S208 further includes measuring a sheet resistance value and a corresponding metal doping concentration on different thicknesses of the nitride channel layer 40 to obtain a plurality of sheet resistance values and a plurality of corresponding metal doping concentration values, and taking two distinct sheet resistance values of the sheet resistance values to obtain the two corresponding metal doping concentration values X1 and X2.

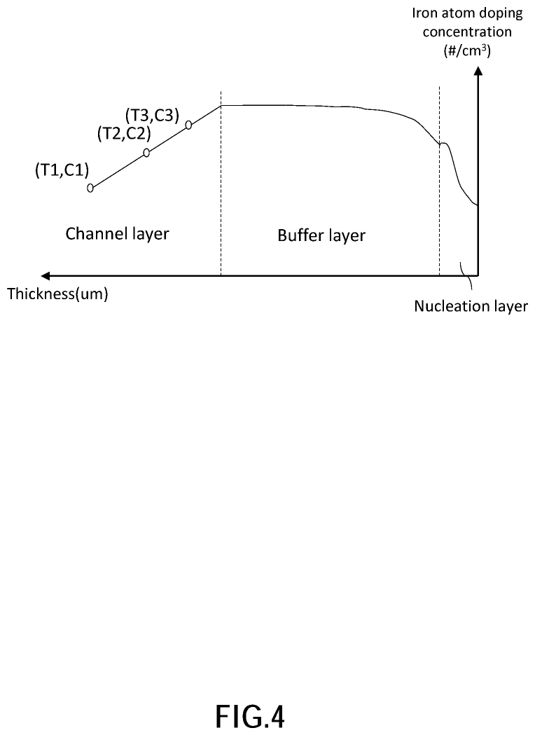

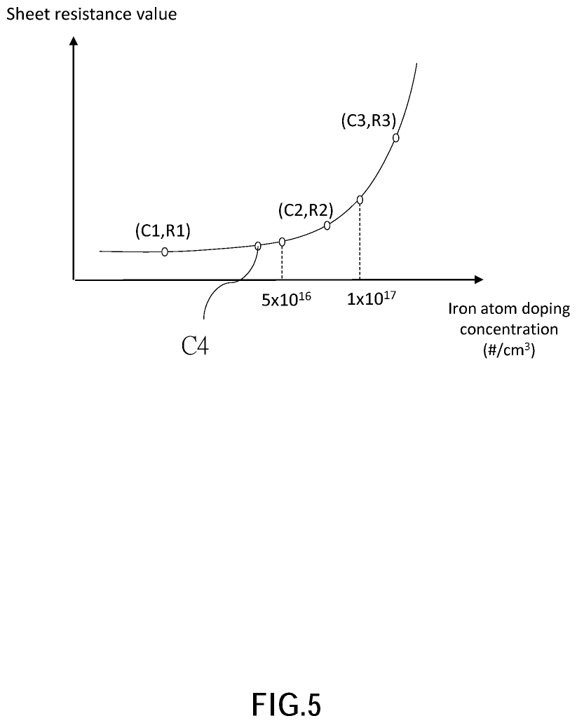

For example, the step S202 is performed to provide a SiC substrate and to form an aluminum nitride nucleation layer on the substrate through metal organic chemical vapor deposition (MOCVD);
the step S204 is performed that a gallium nitride buffer layer is formed on a top of the aluminum nitride nucleation layer under epitaxial growth conditions of a temperature between 1030 degrees Celsius and 1070 degrees Celsius, a pressure between 150 torrs and 250 torrs, and a V/III ratio between 200 and 1500, which are satisfied through MOCVD, and an iron atom doping process is simultaneously performed, and at the same time a flow rate of ferrocene (Cp₂Fe) is controlled at a constant, making an iron atom doping concentration in the gallium nitride buffer layer a constant at 5×10¹⁸ cm⁻³;
then the step S206 is performed to stop the iron atom doping process and to form a gallium nitride channel layer, which has a thickness between 0.6 μm and 1.2 μm, on a top of the gallium nitride buffer layer under epitaxial growth conditions of a temperature between 1030 degrees Celsius and 1070 degrees Celsius, a pressure between 150 torrs and 250 torrs, and a V/III ratio between 200 and 1500, which are satisfied through MOCVD, wherein a total thickness of the gallium nitride buffer layer and the gallium nitride channel layer is less than or equal to 2 μm;
afterwards, the step S208 is performed; as shown in FIG. 4, iron atom doping concentration values C1, C2, and C3 respectively corresponding to different thicknesses T1, T2, and T3 of the gallium nitride channel layer are obtained, and a change C in a metal doping concentration per a unit thickness of the nitride channel layer is calculated; in the current embodiment, C=1/0.2171;
then, the step S210 is performed to obtain sheet resistance values R1, R2, and R3 respectively corresponding to the different thicknesses T1, T2, and T3 of the gallium nitride channel layer; as shown in FIG. 5, a regression curve is plotted by taking the sheet resistance values as a Y axis and the iron atom doping concentrations as a X axis; through the regression curve, when the iron atom doping concentration value is less than a fixed value C4, a change in the sheet resistance value approaches 0 while the iron atom doping concentration value decreases, and two distinct iron atom doping concentration values at 5×10¹⁶ cm⁻³ and 1×10¹⁷ cm⁻³ are correspondingly obtained near the fixed value C4; the iron atom doping concentration value is limited between the two distinct iron atom doping concentration values at 5×10¹⁶ cm⁻³ and 1×10¹⁷ cm⁻³; when a metal doping concentration of the gallium nitride buffer layer at the interface between the gallium nitride buffer layer and the gallium nitride channel layer is X, and a thickness of the gallium nitride channel layer is Y, and 5×10¹⁶≤X−C*Y≤1×10¹⁷ is satisfied, (0.2171)ln(X)−8.54≤Y≤(0.2171)ln(X)−8.34 is deduced. In the current example, three different thickness values, iron atom doping concentration values, and sheet resistance values are taken as an example for illustration. In other embodiments, more than three thickness values, iron atom doping concentration values, and sheet resistance values are not limited.

With the aforementioned design, through satisfying Y≤(0.2171)ln(X)−8.34, the influence of the metal dopant to the sheet resistance value of the nitride channel layer could be reduced and an improved HEMT structure having a better performance could be provided. When the metal doping concentration X is a constant, the maximum value of the thickness Y of the nitride channel layer could be calculated, thereby obtaining the optimum range of the thickness of the nitride channel layer corresponding to the metal doping concentration. When the thickness Y of the nitride channel layer is a constant, the minimum value of the metal doping concentration X could be calculated, thereby obtaining the optimum range of the metal doping concentration corresponding to the thickness of the nitride channel layer. Additionally, as the dopant doping concentration of the channel layer at the interface between the channel layer and the barrier layer is equal to or greater than 1×10¹⁵ cm⁻³, the improved HEMT structure of the present invention could reduce the influence of the metal dopant to the sheet resistance value of the nitride channel layer and could provide the improved HEMT structure having a better performance.

It must be pointed out that the embodiments described above are only some preferred embodiments of the present invention. All equivalent structures and methods which employ the concepts disclosed in this specification and the appended claims should fall within the scope of the present invention.

What is claimed is:

1. An improved high electron mobility transistor (HEMT) structure, comprising in order:
a substrate;
a nucleation layer;
a buffer layer comprising a dopant;
a channel layer having a dopant doping concentration less than a dopant doping concentration of the buffer layer; and
a barrier layer, wherein a two-dimension electron gas is formed in the channel layer along an interface between the channel layer and the barrier layer;
wherein a dopant doping concentration of the channel layer at an interface between the channel layer and the barrier layer is equal to or greater than 1×10¹⁵ cm⁻³.

2. The improved HEMT structure as claimed in claim 1, wherein the dopant is iron.

3. The improved HEMT structure as claimed in claim 1, wherein the dopant doping concentration of the channel layer at the interface between the channel layer and the barrier layer is equal to or greater than 1×10¹⁶ cm⁻³ and is less than or equal to 2×10¹⁷ cm⁻³.

4. The improved HEMT structure as claimed in claim 1, wherein an iron atom concentration of the channel layer gradually decreases in a direction from an interface between the buffer layer and the channel layer to the interface between the channel layer and the barrier layer.

5. The improved HEMT structure as claimed in claim 1, wherein a dopant doping concentration of the buffer layer is equal to or greater than 2×10¹⁷ cm⁻³.

6. The improved HEMT structure as claimed in claim 1, wherein the channel layer is made of aluminum-gallium nitride (AlGaN) or gallium nitride (GaN).

7. The improved HEMT structure as claimed in claim 1, wherein the nucleation layer is made of aluminum nitride (AlN) or aluminum-gallium nitride (AlGaN).

8. The improved HEMT structure as claimed in claim 1, wherein the substrate is a substrate with a resistivity equal to or greater than 1000 Ω/cm.

9. The improved HEMT structure as claimed in claim 1, wherein a total thickness of the buffer layer and the channel layer is less than or equal to 2 μm.

10. The improved HEMT structure as claimed in claim 1, wherein a dopant doping concentration of the buffer layer is evenly distributed on an identical thickness of the buffer layer, and a dopant doping concentration of the channel layer is evenly distributed on an identical thickness of the channel layer.

11. A method of manufacturing an improved high electron mobility transistor (HEMT) structure, comprising steps of:
providing a substrate;
forming a nucleation layer on a top of the substrate;
forming a buffer layer on a top of the nucleation layer and simultaneously performing a doping process;
forming a channel layer on a top of the buffer layer; and
forming a barrier layer on a top of the channel layer, wherein a two-dimension electron gas is formed in the channel layer along an interface between the channel layer and the barrier layer;
wherein a dopant doping concentration of the channel layer at an interface between the channel layer and the barrier layer is equal to or greater than 1×10¹⁵ cm⁻³.

12. The method as claimed in claim 11, wherein iron is doped in the doping process.

13. The method as claimed in claim 11, wherein the dopant doping concentration of the channel layer at an interface between the channel layer and the barrier layer is equal to or greater than 1×10¹⁶ cm⁻³ and is less than or equal to 2×10¹⁷ cm⁻³.

14. The method as claimed in claim 11, wherein an iron atom concentration of the channel layer gradually decreases in a direction from an interface between the buffer layer and the channel layer to the interface between the channel layer and the barrier layer.

15. The method as claimed in claim 11, wherein a dopant doping concentration in the doping process is equal to or greater than 2×10¹⁷ cm⁻³.

16. The method as claimed in claim 11, wherein the channel layer is made of aluminum-gallium nitride (AlGaN) or gallium nitride (GaN).

17. The method as claimed in claim 11, wherein the nucleation layer is made of aluminum nitride (AlN) or aluminum-gallium nitride (AlGaN).

18. The method as claimed in claim 11, wherein the substrate is a substrate with a resistivity equal to or greater than 1000 Ω/cm.

19. The method as claimed in claim 11, wherein a total thickness of the buffer layer and the channel layer is less than or equal to 2 μm.
